(19) United States
(12) Patent Application Publication
(10) Pub. No.: US 2026/0271573 A1
(43) Pub. Date: Sep. 10, 2026

(54) DISPLAY PANEL, EVAPORATION MASK PLATE AND DISPLAY APPARATUS

(71) Applicants: Chongqing BOE Display Technology Co., Ltd., Chongqing (CN); BOE Technology Group Co., Ltd., Beijing (CN)

(72) Inventors: Rui WANG, Beijing (CN); Shouqiang ZHANG, Beijing (CN); Lei ZHU, Beijing (CN)

(21) Appl. No.: 19/166,401

(22) PCT Filed: May 24, 2024
(86) PCT No.: PCT/CN2024/095225

§ 371 Date: Sep. 17, 2025

(30) Foreign Application Priority Data
Jun. 7, 2023 (CN) 202310673137.2

(51) Int. Cl. H10K 59/35; H10K 71/16

(52) U.S. Cl. CPC H10K 59/353; H10K 71/166

(57) ABSTRACT

A display panel includes at least two types of subpixel regions, where each subpixel region is provided with a subpixel, and each subpixel region of at least one type is provided with at least two subpixels. A luminescent material of all subpixels in any subpixel region is obtained by means of one opening in a mask plate. A distance between two adjacent subpixel regions is greater than a distance between two adjacent subpixels in the same subpixel region. Two adjacent columns of subpixel regions in a first direction include different colors of subpixel regions. The distance between two adjacent subpixel regions of the same type in one of the two adjacent columns is a first distance, a size of another type of subpixel region in the other column in the first direction is a second distance, and the first distance is less than the second distance.

### CROSS-REFERENCE TO RELATED APPLICATIONS

The present application claims priority from the Chinese patent application No. 2023106731372 filed on Jun. 7, 2023, the entire contents of which are incorporated herein by reference.

### TECHNICAL FIELD

The present disclosure relates to the field of display technology, and in particular relates to a display panel, an evaporation mask plate and a display apparatus.

### BACKGROUND

Current organic light-emitting diode (OLED) devices are generally formed by evaporating an organic luminescent material onto an array substrate, where the organic luminescent material is evaporated on an anode in an opening of a pixel defining layer on the array substrate, and the openings in the pixel defining layer are configured to define an actual light-emitting area. An aperture area of the pixel is typically increased by reducing a size between openings in the pixel defining layer to improve the display brightness. However, limited by the manufacturing process accuracy of the evaporation mask plate, it is difficult to further reduce the size between the openings in the pixel defining layer, and thus difficult to further increase the aperture ratio of the display panel. As a result, it is difficult to further improve the display brightness of the conventional display panel.

### SUMMARY

Some embodiments of the present disclosure provide a display panel, an evaporation mask plate and a display apparatus, which can further increase the aperture ratio of the display panel, and further improve the display brightness of the display panel.

In a first aspect of the present disclosure, there is provided a display panel, including: at least two types of subpixel regions, wherein each type of subpixel region is configured to emit one color of light, each subpixel region is provided with a subpixel, and each subpixel is provided with a luminescent material. Each subpixel region of at least one type of subpixel regions is provided with at least two subpixels; the luminescent material of all the subpixels in any subpixel region are obtained by means of one opening provided in an evaporation mask plate; a distance between two adjacent subpixel regions is greater than a distance between two adjacent subpixels in the same subpixel region; and two adjacent columns of subpixel regions arranged in a first direction include different colors of subpixel regions, a distance between two adjacent subpixel regions of the same type in one of the two adjacent columns is a first distance, a size of another type of subpixel region in the other of the two adjacent columns in the first direction is a second distance, and the first distance is less than the second distance.

According to a first aspect of the present disclosure, in some embodiments, the display panel further includes a pixel defining layer between adjacent subpixels. Each subpixel region of at least one type of subpixel regions is provided with at least two subpixels, and each subpixel region of at least one type of subpixel regions is provided with one subpixel; or, each subpixel region of all the subpixel regions is provided with at least two subpixels.

According to the first aspect of the present disclosure, in some embodiments, the subpixel regions include a red subpixel region, a green subpixel region, and a blue subpixel region, and the subpixels include a red subpixel, a green subpixel, and a blue subpixel; each blue subpixel region is provided with at least two blue subpixels; each red subpixel region is provided with one red subpixel; and each green subpixel region is provided with one green subpixel.

According to the first aspect of the present disclosure, in some embodiments, the display panel further includes a plurality of pixel units. Each blue subpixel region is provided with four blue subpixels, each pixel unit includes one red subpixel, one green subpixel, and two blue subpixels.

According to the first aspect of the present disclosure, in some embodiments, red subpixels and green subpixels are alternately arranged in the first direction; blue subpixels are arranged consecutively in the first direction; and a size of the blue subpixel in the first direction is less than a size of the red subpixel in the first direction, and/or the size of the blue subpixel in the first direction is less than a size of the green subpixel in the first direction.

According to the first aspect of the present disclosure, in some embodiments, the subpixel regions include a red subpixel region, a green subpixel region, and a blue subpixel region, and the subpixels include a red subpixel, a green subpixel, and a blue subpixel; each blue subpixel region is provided with at least three blue subpixels; each red subpixel region is provided with at least two red subpixels; and each green subpixel region is provided with at least two green subpixels.

According to the first aspect of the present disclosure, in some embodiments, each blue subpixel region is provided with six blue subpixels, each red subpixel region is provided with four red subpixels, and each green subpixel region is provided with four green subpixels; or, some blue subpixel regions are each provided with three blue subpixels, while some blue subpixel regions are each provided with six blue subpixels; some red subpixel regions are each provided with two red subpixels, while some red subpixel regions are each provided with four red subpixels; and some green subpixel regions are each provided with two green subpixels, while some green subpixel regions are each provided with four green subpixels.

According to the first aspect of the present disclosure, in some embodiments, the display panel further includes: a plurality of pixel units, each of which includes one red subpixel, one green subpixel, and one blue subpixel.

According to the first aspect of the present disclosure, in some embodiments, blue subpixel regions are arranged consecutively in the first direction; red subpixel regions and green subpixel regions are alternately arranged in the first direction; and a size of the blue subpixel in the first direction is greater than a size of the red subpixel in the first direction, and/or the size of the blue subpixel in the first direction is greater than a size of the green subpixel in the first direction.

According to the first aspect of the present disclosure, in some embodiments, in a second direction, blue subpixel regions and red subpixel regions are alternately arranged, and/or blue subpixel regions and green subpixel regions are alternately arranged; and the first direction intersects with the second direction.

According to the first aspect of the present disclosure, in some embodiments, a distance between adjacent blue subpixel regions in the first direction is the first distance; and a minimum size of the red or green subpixel region in the first direction is the second distance.

According to the first aspect of the present disclosure, in some embodiments, a distance between adjacent blue subpixel regions in the first direction is the first distance, a shortest distance between the red subpixel region and the green subpixel region adjacent in the first direction is a third distance, and the first distance is greater than the third distance.

According to the first aspect of the present disclosure, in some embodiments, a size of the blue subpixel region in the first direction is greater than a size of the red subpixel region in the first direction, and/or the size of the blue subpixel region in the first direction is greater than a size of the green subpixel region in the first direction.

According to the first aspect of the present disclosure, in some embodiments, at least one type of the subpixel regions each have a rectangular shape, and the subpixel regions in the at least one type of the subpixel regions each have a rectangular shape; an aspect ratio of the shape of the subpixel regions in the at least one type of the subpixel regions is equal to an aspect ratio of a shape of a corresponding subpixel; and/or, an aspect ratio of the shape of the subpixel regions in the at least one type of the subpixel regions is greater than an aspect ratio of the shape of the corresponding subpixel.

According to the first aspect of the present disclosure, in some embodiments, a difference between the number of rows and the number of columns of all the subpixels arranged in each subpixel region is 2 or less.

According to the first aspect of the present disclosure, in some embodiments, the blue subpixel region is provided with three blue subpixels, and the three blue subpixels in the same blue subpixel region are arranged in a single column in the first direction; or, the blue subpixel region is provided with six blue subpixels, and the six blue subpixels in the same blue subpixel region are arranged in two columns in the first direction.

According to the first aspect of the present disclosure, in some embodiments, two adjacent columns of subpixel regions in the first direction correspond to different colors of emitted light.

In a second aspect of the present disclosure, there is provided an evaporation mask plate for preparing the display panel according to the first aspect. The evaporation mask plate includes: at least two types of openings, each type configured for correspondingly preparing a luminescent material of one type of subpixel regions in the display panel. Each opening is configured for correspondingly preparing the luminescent material of one subpixel region of the display panel; a distance between adjacent openings of the two types is greater than a distance between two adjacent subpixels in the same subpixel region of the display panel; and two adjacent columns of openings in the first direction include different types of openings for preparing different colors of luminescent materials, a distance between two adjacent openings of the same type in one of the two adjacent columns is a fourth distance, a size of another type of opening in the other of the two adjacent columns in the first direction is a fifth distance, and the fourth distance is less than the fifth distance.

In a third aspect of the present disclosure, there is provided a display apparatus, including: the display panel according to the first aspect.

### BRIEF DESCRIPTION OF FIGURES

The above and various other advantages and benefits of the present disclosure will become apparent to those of ordinary skill in the art from reading the following detailed description of preferred implementations.

FIG. 1 is a partial structural diagram of a display panel according to some embodiments of the present disclosure;

FIG. 2 is a schematic diagram showing a pixel arrangement in an existing display panel;

FIG. 3 is a partial structural diagram of a display panel according to some other embodiments of the present disclosure;

FIG. 4 is a partial structural diagram of a display panel according to still other embodiments of the present disclosure;

FIG. 5 is a partial structural diagram of a display panel according to yet other embodiments of the present disclosure;

FIG. 6 is a partial structural diagram of a display panel according to some other embodiments of the present disclosure;

FIG. 7 is a partial structural diagram of an evaporation mask plate according to some embodiments of the present disclosure;

FIG. 8 is a partial structural diagram of an evaporation mask plate according to some other embodiments of the present disclosure; and

FIG. 9 is a schematic structural diagram of a display apparatus according to some embodiments of the present disclosure.

### DETAILED DESCRIPTION

To better understand the technical solutions provided in the embodiments of the present disclosure, the technical solutions provided in the embodiments of the present disclosure will be described in detail below with reference to the accompanying drawings and specific embodiments. It should be understood that the embodiments of the present disclosure and specific features in the embodiments are detailed description of the technical solutions provided in the embodiments of the present disclosure, but not limitations to the technical solutions of the present disclosure, and the embodiments of the present disclosure and technical features thereof may be combined with each other as long as they are not contradictory.

In this context, relational terms, such as first and second, are used merely to distinguish one entity or operation from another without necessarily requiring or implying that there is any such actual relationship or order between such entities or operations. Moreover, the term “include”, “comprise” or any variant thereof means to be non-exclusive so that a process, method, item or device including a series of elements includes not only said elements, but also other elements not explicitly listed, or inherent elements of such processes, methods, items or devices. In the absence of more limitations, an element defined by “comprising a . . . ” does not exclude the existence of additional identical elements in the process, method, item or device including the element. The terms “a plurality of” and “two or more” include the case of two or more. The term “and/or” is merely to describe an association relationship of associated objects, which may include three relationships; for example, A and/or B may refer to: A alone, A and B, or B alone.

Current organic light-emitting diode (OLED) devices are generally formed by evaporating an organic luminescent material onto an array substrate, where the organic luminescent material is evaporated on an anode in an opening of a pixel defining layer in the array substrate, and the openings in the pixel defining layer are configured to define an actual light-emitting area. An aperture area of the pixel is typically increased by reducing a size between openings in the pixel defining layer to improve the display brightness. However, limited by the manufacturing process accuracy of the evaporation mask plate, it is difficult to further reduce the size between the openings in the pixel defining layer, and thus difficult to further increase the aperture ratio of the display panel. As a result, it is difficult to further improve the display brightness of the conventional display panel.

In view of this, some embodiments of the present disclosure provide a display panel, an evaporation mask plate and a display apparatus, which can further increase the aperture ratio of the display panel, and further improve the display brightness of the display panel.

Some embodiments of the present disclosure provide a display panel, including at least two types of subpixel regions, where each type of subpixel region is configured to emit one color of light. Each subpixel region is provided with a subpixel, and each subpixel is provided with a luminescent material. The luminescent material is used for emitting light to display a picture. Each subpixel region of at least one type of subpixel regions is provided with at least two subpixels; the luminescent material of all the subpixels in any one subpixel region is obtained by means of one opening provided in a mask plate; and instead of increasing a display aperture ratio of the display panel by reducing only a distance between the subpixels, a distance between the subpixels in the same subpixel region, and a distance between adjacent subpixel regions, can be independently set. Since each subpixel region of at least one type of subpixel regions is provided with at least two subpixels, a total area of the regions between the openings in the display panel as a whole can be reduced, thereby serving to increase the aperture ratio of the display panel.

In addition, a distance between two adjacent subpixel regions is greater than a distance between two adjacent subpixels in the same subpixel region, which may be understood as that a distance between adjacent subpixel regions of different colors is greater than a distance between adjacent subpixels of the same color. The distance between adjacent subpixel regions is limited by openings in the evaporation mask plate, while the distance between the subpixels in the same subpixel region is limited by a distance between openings in a pixel defining layer. Therefore, with at least two or more subpixels corresponding to the same opening in the evaporation mask plate, the number of openings in the evaporation mask plate can be reduced, which can further reduce the area occupied by regions between the openings in the evaporation mask plate, and increase the aperture ratio of the evaporation mask plate, and by preparing the luminescent material of the corresponding display panel with the evaporation mask plate having the increased aperture ratio, a pixel structure of the display panel having an increased aperture ratio can be obtained.

Two adjacent columns of subpixel regions arranged in a first direction include different colors of subpixel regions, the distance between two adjacent subpixel regions of the same type in one of the two columns is a first distance, a size of another type of subpixel region in the other of the two adjacent columns in the first direction is a second distance, and the first distance is less than the second distance. The first direction may be any direction, and the distance between adjacent subpixel regions of the same color in the first direction cannot be greater than the size of any adjacent column of subpixel regions of other colors, so as to ensure an increased aperture ratio of the display panel.

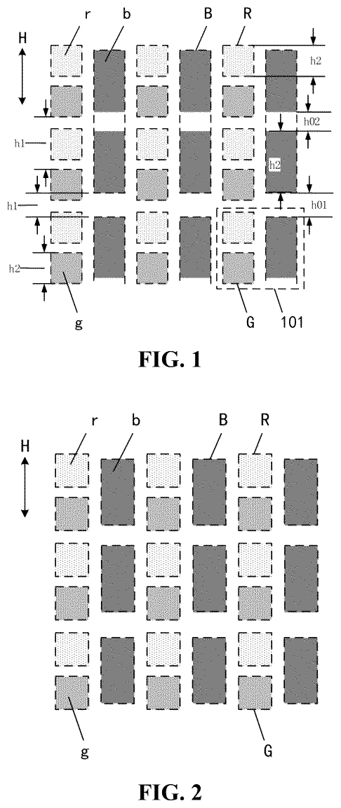

Illustratively, FIG. 1 is a partial structural diagram of a display panel according to some embodiments of the present disclosure. As shown in FIG. 1, in some implementations, the display panel includes three subpixel regions, which are a red subpixel region R, a green subpixel region G, and a blue subpixel region B, respectively. The red subpixel region R includes a red subpixel r, the green subpixel region G includes a green subpixel g, and the blue subpixel region B includes a blue subpixel b. The red subpixel r includes a red luminescent material for emitting red light, the green subpixel g includes a green luminescent material for emitting green light, and the blue subpixel b includes a blue luminescent material for emitting blue light. Each blue subpixel region B is provided with two blue subpixels b, each red subpixel region R is provided with one red subpixel r, and each green subpixel region G is provided with one green subpixel g. One red subpixel region R corresponds to one opening in the evaporation mask plate, one green subpixel region G corresponds to one opening in the evaporation mask plate, and one blue subpixel region B corresponds to one opening in the evaporation mask plate. In other words, two blue subpixels b in the same blue subpixel region B in FIG. 1 correspond to the same opening in the evaporation mask plate. A distance between the two blue subpixels b in the same blue subpixel region B may be limited by openings in a pixel defining layer. In other words, a size of the subpixel corresponds to the opening in the pixel defining layer. The distance between the two blue subpixels b in the same blue subpixel region B is a second spacing h02, a distance between two adjacent blue subpixel regions B is a first spacing h01, and the first spacing h01 is greater than the second spacing h02. Therefore, the aperture ratio of the display panel can be increased by simultaneously reducing the first spacing h01 and the second spacing h02. The second spacing h02 can be reduced by the arrangement of openings in the pixel defining layer, the first spacing h01 can be reduced by the arrangement of openings in the evaporation mask plate, and synchronous reduction of the two sizes can further increase the aperture ratio of the display panel. The limitation to the process accuracy when the aperture ratio is increased by only reducing the second spacing h02 can be broken through, because when the second distance h02 is reduced to the process limit, the aperture ratio of the display panel can be further increased by reducing the second spacing h02. In addition, the luminescent material is prepared in all the subpixels in one subpixel region of the display panel corresponding to one opening in the evaporation mask plate, so that the number of subpixel regions in the display panel can be reduced. In other words, the number of second spacings h02 in the display panel, and thus an area occupied by the regions with the second spacings h02 in the display panel, can be reduced. Therefore, an area of the regions occupied by the subpixels can be increased to increase the aperture ratio of the display panel, which breaks through the technical bottleneck of increasing the aperture ratio without improving the process capability.

With continued reference to FIG. 1, in some implementations, the blue subpixel region B and the red subpixel region R arranged in a first direction H belong to two adjacent columns, and the blue subpixel region B and the green subpixel region G in the first direction H belong to two adjacent columns. The red subpixel region R and the green subpixel region G in the first direction H may be in the same column (as shown in FIG. 1), or may be in two adjacent columns in other implementations. In two adjacent columns of subpixel regions, one column includes blue subpixels b, and the other column includes red subpixels r and green subpixels g. A distance between two adjacent green subpixel regions G in one of the two adjacent columns is a first distance h1, and a size of the blue subpixel region in the other of the two adjacent columns in the first direction is a second distance h2. A distance between two adjacent blue subpixel regions B in one of the two adjacent columns is the first distance h1, a size of the green subpixel region G in the other of the two adjacent columns in the first direction H is the second distance h2, and a size of the red subpixel region R in the first direction H is the second distance h2. The first distance h1 is less than the second distance h2, and it should be noted that the first distance h1 and the second distance h2 are defined relative to two adjacent columns, not the same column. The first direction H may be any direction, and the distance between adjacent subpixel regions of the same color in the first direction H cannot be greater than the size of the subpixel region of other color in any adjacent column, so as to ensure an increased aperture ratio of the display panel.

It should be noted that the subpixel regions shown in FIG. 1 are illustrated with dashed lines.

It should be noted that in a pixel structure of a typical display panel, one subpixel corresponds to one opening in the evaporation mask plate. For example, FIG. 2 is a schematic diagram showing a pixel arrangement in an existing display panel. As shown in FIG. 2, one red subpixel region R corresponds to one red subpixel r, and one red subpixel r corresponds to one opening in the evaporation mask plate; one green subpixel region G corresponds to one green subpixel g, and one green subpixel g corresponds to one opening in the evaporation mask plate; and one blue subpixel region B corresponds to one blue subpixel b, and one blue subpixel b corresponds to one opening in the evaporation mask plate. In this arrangement, openings of the subpixels are mainly limited by the openings in the pixel defining layer, and if a distance between the openings in the pixel defining layer is reduced, the size of the openings in the pixel defining layer will be increased, thereby increasing the aperture ratio of the display panel. However, if the distance between the openings in the pixel defining layer is too small, color mixing between subpixels of different colors tends to occur, causing color shift and affecting the display chromaticity. In addition, due to the limited process capability of the evaporation mask plate, the reduction of the distance between openings in the evaporation mask plate is also correspondingly limited, causing a technical bottleneck in the improvement of the aperture ratio of the display panel in the existing art.

In the display panel according to some embodiments of the present disclosure, each subpixel region of at least one type of subpixel regions is provided with at least two subpixels; the luminescent material of all the subpixels in any one subpixel region is obtained by means of one opening provided in a mask plate; and instead of increasing a display aperture ratio of the display panel by reducing only a distance between the subpixels, a distance between the subpixels in the same subpixel region, and a distance between adjacent subpixel regions, can be independently set. Since each subpixel region of at least one type of subpixel regions is provided with at least two subpixels, a total area of the regions between the openings in the display panel as a whole can be reduced, thereby serving to increase the aperture ratio of the display panel. In addition, a distance between two adjacent subpixel regions is greater than a distance between two adjacent subpixels in the same subpixel region, a distance between adjacent subpixel regions of different colors is greater than a distance between adjacent subpixels of the same color, and the distance between adjacent subpixel regions is limited by openings in the evaporation mask plate, while the distance between the subpixels in the same subpixel region is limited by a distance between openings in a pixel defining layer. Therefore, with at least two or more subpixels corresponding to the same opening in the evaporation mask plate, the number of openings in the evaporation mask plate can be reduced, which can further reduce the area occupied by regions between the openings in the evaporation mask plate, and increase the aperture ratio of the evaporation mask plate, and by preparing the luminescent material of the corresponding display panel with the evaporation mask plate having the increased aperture ratio, a pixel structure of the display panel having an increased aperture ratio can be obtained. Two adjacent columns of subpixel regions arranged in a first direction include different colors of subpixel regions, the distance between two adjacent subpixel regions of the same type in one of the two adjacent columns is a first distance, a size of another type of subpixel region in the other of the two adjacent columns in the first direction is a second distance, and the first distance is less than the second distance, so as to ensure an increased aperture ratio of the display panel.

In some implementations, a pixel defining layer is provided between adjacent subpixels. Each subpixel region of at least one type of subpixel regions is provided with at least two subpixels, and each subpixel region of at least one type of subpixel regions is provided with one subpixel.

As shown in FIG. 1, in some implementations, each blue subpixel region B is provided with two blue subpixels b, each red subpixel region R is provided with one red subpixel r, and each green subpixel region G is provided with one green subpixel g, so that one red subpixel r, one green subpixel g and one blue subpixel b can be combined into one pixel unit 101 as one color mixing unit.

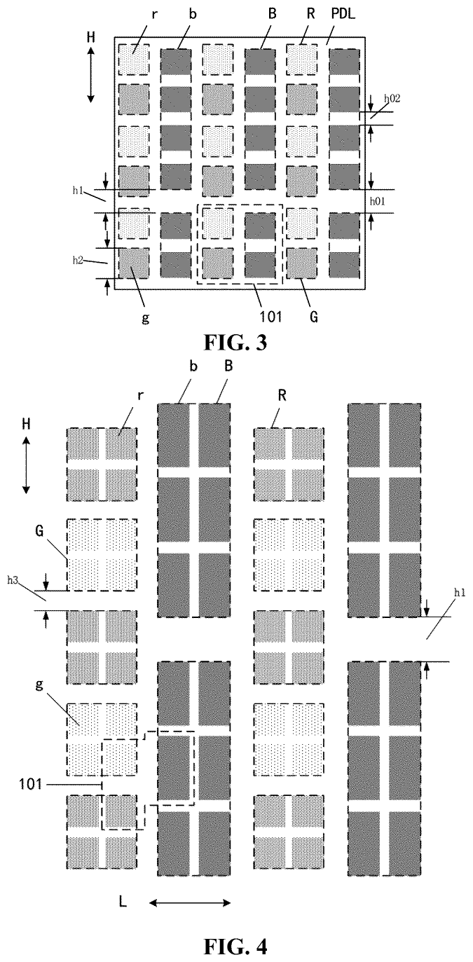

Illustratively, FIG. 3 is a partial structural diagram of a display panel according to some other embodiments of the present disclosure. As shown in FIG. 3, a pixel defining layer PDL is provided between any adjacent subpixels. Each blue subpixel region B is provided with four blue subpixels b, each red subpixel region R is provided with one red subpixel r, and each green subpixel region G is provided with one green subpixel g, so that one red subpixel r, one green subpixel g and two blue subpixels b can be combined into one pixel unit 101.

In the display panel shown in FIG. 3, the distance between the blue subpixel regions B is reduced, which, for a display panel with low PPI (resolution), can alleviate the grainy sense of the image, and reduce the visible graininess of the display panel.

In some implementations, since the blue luminescent material exhibits greater light attenuation than the red and green luminescent materials, the blue subpixel in one pixel unit 101 generally takes a larger area.

In some implementations, referring to FIGS. 1 and 3, red subpixels r and green subpixels g are alternately arranged in the first direction H; and blue subpixels b are arranged consecutively in the first direction H.

In some implementations, referring to FIG. 1, since each pixel unit 101 includes one blue subpixel b, red subpixels r and green subpixels g are arranged in the same column, while blue subpixels b are arranged in a single column, to ensure a sufficient area for the blue subpixels b in the column direction, i.e., the first direction H, it is necessary to provide that a size of the blue subpixel b in the first direction H is greater than a size of the green subpixel g in the first direction H, and the size of the blue subpixel b in the first direction H is greater than a size of the red subpixel r in the first direction H.

In some implementations, referring to FIG. 3, since each pixel unit 101 includes two blue subpixels b, a size of each blue subpixel b in the first direction H is less than a size of the red subpixel r in the first direction H, and the size of the blue subpixel b in the first direction H is less than a size of the green subpixel g in the first direction H.

In some implementations, each blue subpixel region B is provided with at least three blue subpixels b; each red subpixel region R is provided with at least two red subpixels r; and each green subpixel region G is provided with at least two green subpixels g.

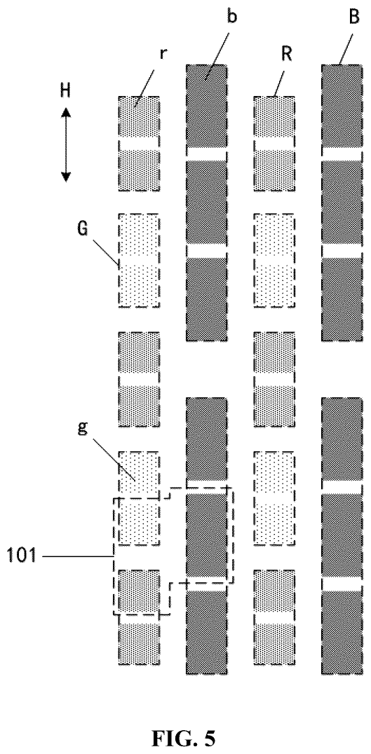

Illustratively, FIG. 4 is a partial structural diagram of a display panel still other embodiments of the present disclosure. As shown in FIG. 4, each blue subpixel region B is provided with six blue subpixels b, each red subpixel region R is provided with four red subpixels r, and each green subpixel region G is provided with four green subpixels g. In this case, each of the pixel units 101 may include one blue subpixel b, one red subpixel r, and one green subpixel g.

Illustratively, FIG. 5 is a partial structural diagram of a display panel according to yet other embodiments of the present disclosure. As shown in FIG. 5, each blue subpixel region B is provided with three blue subpixels b, each red subpixel region R is provided with four red subpixels r, and each green subpixel region G is provided with four green subpixels g. In this case, each of the pixel units 101 may include one blue subpixel b, one red subpixel r, and one green subpixel g.

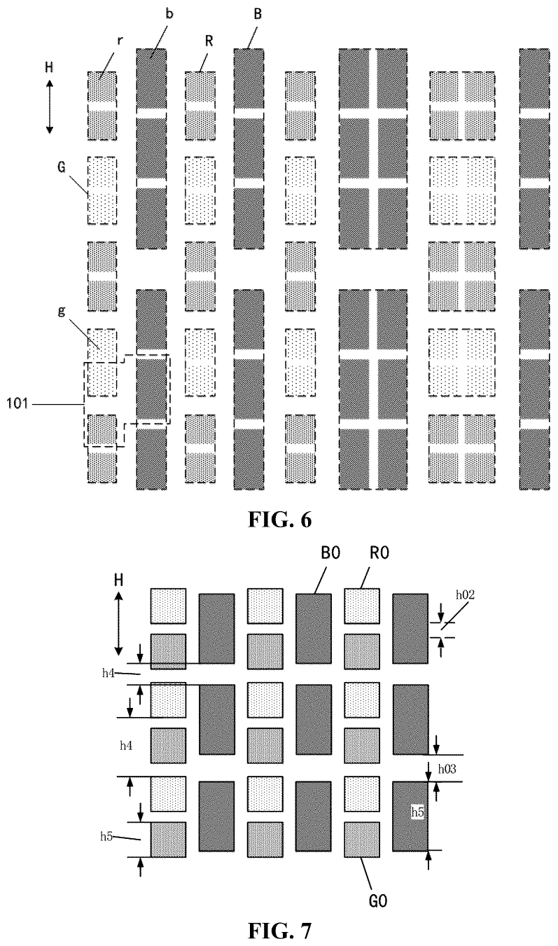

Illustratively, FIG. 6 is a partial structural diagram of a display panel according to some other embodiments of the present disclosure. As shown in FIG. 6, some blue subpixel regions B are each provided with three blue subpixels b, while other blue subpixel regions B are each provided with six blue subpixels b; some red subpixel regions R are each provided with two red subpixels r, while other red subpixel regions R are each provided with four red subpixels r; and some green subpixel regions G are each provided with two green subpixels g, while other green subpixel regions G are each provided with four green subpixels g. In this case, each of the pixel units 101 may include one blue subpixel b, one red subpixel r, and one green subpixel g.

In some implementations, at least one type of the subpixel regions may have a rectangular shape, and the subpixel regions in at least one type of the subpixel regions may have a rectangular shape.

In some implementations, referring to FIGS. 1 and 3 to 6, the red subpixel region R, the red subpixel r, the green subpixel region G, the green subpixel g, the blue subpixel region B, and the blue subpixel b may each have a rectangular shape. The red subpixel r and the green subpixel g may each have a square shape. In some other implementations, referring to FIG. 4, the red subpixel region R and the green subpixel region G may also each have a square shape.

In some implementations, an aspect ratio of the shape of the subpixel regions in at least one type of the subpixel regions is equal to an aspect ratio of the shape of the corresponding subpixel. It should be noted that in a rectangle, the aspect ratio is a ratio of length to width.

In some implementations, referring to FIGS. 1 and 4, an aspect ratio of the shape of the red subpixel region R is equal to an aspect ratio of the shape of the red subpixel r, and an aspect ratio of the shape of the green subpixel region G is equal to an aspect ratio of the shape of the green subpixel g, i.e., both ratios are 1:1.

In some implementations, an aspect ratio of the shape of the subpixel regions in at least one type of the subpixel regions is greater than an aspect ratio of the shape of the corresponding subpixel.

In some implementations, referring to FIGS. 1 and 3 to 6, an aspect ratio of the shape of the blue subpixel region B is greater than an aspect ratio of the shape of the blue subpixel b.

In some implementations, a difference between the number of rows and the number of columns of all the subpixels arranged in each subpixel region is 2 or less.

In some implementations, referring to FIG. 1, the blue subpixels b in the blue subpixel region B are arranged in a single column, and 2 rows of blue subpixels b are arranged in each blue subpixel region B, so the number of rows and the number of columns differ by 1.

In some implementations, referring to FIG. 4, the blue subpixels b in the blue subpixel region B are arranged in 3 rows and 2 columns, so the number of rows and the number of columns differ by 1. The red subpixels r in the red subpixel region R are arranged in 2 rows and 2 columns, so the number of rows and the number of columns differ by 0.

In some implementations, referring to FIG. 5, the blue subpixels b in the blue subpixel region B are arranged in 3 rows and 1 column, so the number of rows and the number of columns differ by 2.

By controlling the difference between the number of rows and the number of columns of the subpixel arrangement in the subpixel region, the pixel units can be arranged and combined to achieve a higher space utilization rate, thereby facilitating a reasonable arrangement of pixels.

In some implementations, referring to FIGS. 4 to 6, blue subpixel regions B are arranged consecutively in the first direction H; and red subpixel regions R and green subpixel regions G are alternately arranged in the first direction H. A size of the blue subpixel b in the first direction H is greater than a size of the red subpixel r in the first direction; and the size of the blue subpixel b in the first direction H is greater than a size of the green subpixel g in the first direction H.

In some implementations, referring to FIGS. 4 to 6, in a second direction L, blue subpixel regions B and red subpixel regions R are alternately arranged, and blue subpixel regions B and green subpixel regions G are alternately arranged. The first direction H intersects with the second direction L. For example, the first direction H may be perpendicular to the second direction L. The first direction H may be a column direction, and the second direction L may be a row direction.

In some implementations, referring to FIG. 4, a distance between adjacent blue subpixel regions B in the first direction H is the first distance h1, a shortest distance between the red subpixel region R and the green subpixel region G adjacent in the first direction H is a third distance h3, and the first distance h1 is greater than the third distance h3.

In some implementations, referring to FIGS. 4 to 6, a size of the blue subpixel region B in the first direction H is greater than a size of the red subpixel region R in the first direction H; and the size of the blue subpixel region B in the first direction H is greater than a size of the green subpixel region G in the first direction.

In some implementations, referring to FIGS. 5 and 6, under the condition that the blue subpixel region B is provided with three blue subpixels b, the three blue subpixels b in the same blue subpixel region B are arranged in a single column in the first direction H, i.e., in a single-column arrangement.

In some implementations, referring to FIGS. 4 and 6, under the condition that the blue subpixel region B is provided with six blue subpixels b, the six blue subpixels b in the same blue subpixel region B are arranged in two columns in the first direction H, i.e., in a double-column arrangement, which can facilitate arrangement and division of the pixel units.

Illustratively, table 1 shows aperture ratio data corresponding to different pixel structures.

TABLE 1

| Figure corresponding to pixel arrangement embodiment | FIG. 2 | FIG. 1 | FIG. 3 | FIG. 5 | FIG. 4 |
|---|---|---|---|---|---|
| Size between openings in pixel defining layer (μm) | 19 | 19 | 19 | 19 | 19 |
| Distance between pixel units (μm) | 89.7 | 89.7 | 89.7 | 89.7 | 89.7 |
| Distance between openings in evaporation mask plate | 27 | 27 | 27 | 27 | 27 |
| Aperture ratio of red subpixel | 6.59% | 7.86% | 7.11% | 8.84% | 10.21% |
| Aperture ratio of green subpixel | 7.91% | 9.43% | 8.53% | 10.61% | 12.25% |
| Aperture ratio of blue subpixel | 15.82% | 18.86% | 17.07% | 21.23% | 24.51% |
| Aperture ratio of pixel unit | 30.32% | 36.15% | 32.71% | 40.68% | 46.96% |
| Increase in aperture ratio of pixel unit compared | / | 19.21% | 7.87% | 34.16% | 54.92% |
| with the embodiment in FIG. 2 | | | | | |

As shown in table 1, compared with the pixel arrangement structure in the existing art shown in FIG. 2, the display panel according to some embodiments of the present disclosure have at least two subpixels in any subpixel region corresponding to one opening in the evaporation mask plate, which can greatly increase the aperture ratio of the display panel, and further improve the display brightness, display effect and display life of the display panel.

Some embodiments of the present disclosure provide an evaporation mask plate for preparing the display panel according to any one of the above embodiments. The evaporation mask plate includes at least two types of openings, each type configured for correspondingly preparing a luminescent material of one type of subpixel regions in the display panel. Each opening is used for correspondingly preparing the luminescent material of one subpixel region of the display panel. A distance between adjacent openings of the two types is greater than a distance between two adjacent subpixels in the same subpixel region of the display panel. Two adjacent columns of openings in the first direction include different types of openings for preparing different colors of luminescent materials, a distance between two adjacent openings of the same type in one of the two adjacent columns is a fourth distance, a size of another type of opening in the other of the two adjacent columns in the first direction is a fifth distance, and the fourth distance is less than the fifth distance.

Illustratively, FIG. 7 is a partial structural diagram of an evaporation mask plate according to some embodiments of the present disclosure. As shown in FIG. 7, the openings include a red opening R0, a green opening G0, and a blue opening B0. The red opening R0 is used for correspondingly preparing a red luminescent material in a red subpixel region R of the display panel, the green opening G0 is used for correspondingly preparing a green luminescent material in a green subpixel region G of the display panel, and the blue opening B0 is used for correspondingly preparing a blue luminescent material in a blue subpixel region B the display panel. Blue openings B0 and red openings R0 are arranged in two adjacent columns, blue openings B0 and green openings G0 are arranged in two adjacent columns, and red openings R0 and green openings G0 may be arranged in the same column, or in adjacent columns. A distance between two adjacent blue openings B0 is a third distance h03, and the third distance h03 is greater than the second distance h02 in the display panel. In the embodiment corresponding to FIG. 7, taking the case where the blue opening B0 is used for preparing two blue subpixels in the same blue subpixel region B as an example, a distance between two adjacent blue subpixels b in the same blue subpixel region B in the display panel is a second spacing h02.

The blue opening B0 and the red opening R0 arranged in the first direction H belong to two adjacent columns, the blue opening B0 and the green opening G0 arranged in the first direction H belong to two adjacent columns, and the red opening R0 and the green opening G0 arranged in the first direction H may belong to the same column or belong to two adjacent columns. A distance between two adjacent red openings R0 in one of the two adjacent columns is a fourth distance h4, and a size of the blue opening B0 in the other of the two adjacent columns in the first direction is a fifth distance h5. A distance between two adjacent blue openings B0 in one of the two adjacent columns is the fourth distance h4, while in the other of the two adjacent columns, a size of the green opening G0 in the first direction H is the fifth distance h5, and a size of the red opening R0 in the first direction H is the fifth distance h5, and the fourth distance h4 is less than the fifth distance h5. It should be noted that the fourth distance h4 and the fifth distance h5 correspond to two adjacent columns, and are not defined in the same column.

In the evaporation mask plate according to some embodiments of the present disclosure, at least one type of openings is provided for correspondingly preparing a luminescent material of one type of subpixel regions in the display panel; each opening is used for correspondingly preparing the luminescent material of one subpixel region of the display panel; and one opening may be used to prepare the luminescent material in at least two subpixels of the display panel. In this manner, the number of openings and the distance between openings can be reduced, so that a total area of the regions between the openings in the display panel as a whole can be reduced, thereby serving to increase the aperture ratio of the display panel. In addition, a distance between adjacent openings of the two types is greater than a distance between two adjacent subpixels in the same subpixel region of the display panel; and two adjacent columns of openings in the first direction include openings for correspondingly preparing different colors of luminescent materials, a distance between two adjacent openings of the same type in one of the two adjacent columns is a fourth distance, a size of another type of opening in the other of the two adjacent columns in the first direction is a fifth distance, and the fourth distance is less than the fifth distance. Therefore, the distance between the openings can be ensured to be reduced to increase an aperture ratio of the display panel.

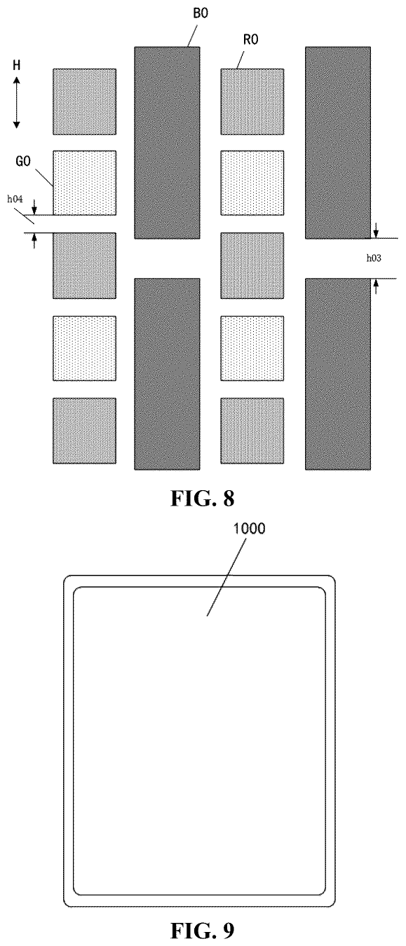

Illustratively, FIG. 8 is a partial structural diagram of an evaporation mask plate according to some other embodiments of the present disclosure. As shown in FIG. 8, blue openings B0 are arranged consecutively in the first direction H; red openings R0 and green openings G0 are alternately arranged in the first direction H; and a distance between adjacent blue openings B0 arranged in the first direction H is a third spacing h03, a distance between a red opening R0 and a green opening G0 arranged adjacent in the first direction H is a fourth spacing h04, and the third spacing h03 is greater than the fourth spacing h04. The distance between specific openings may be set according to the combination requirements of the pixel units. For example, the evaporation mask plate in the embodiment corresponding to FIG. 8 may be used to prepare the display panel in the embodiment corresponding to FIG. 4.

Some embodiments of the present disclosure provide a display apparatus. Illustratively, FIG. 9 is a schematic structural diagram of a display apparatus according to some embodiments of the present disclosure. As shown in FIG. 9, the display apparatus includes the display panel 1000 according to any one of the above embodiments.

It should be noted that the display apparatus provided in the embodiments of the present disclosure may include a smart phone, a tablet, a laptop, a television, a smart wearable display device, and the like, where the smart wearable display device may include a smart watch, which is not specifically limited in the present disclosure.

It should be noted that, in the above embodiments, the description of each embodiment has its own emphasis, and for parts that are not described in detail in a certain embodiment, reference may be made to the related description in other embodiments.

The above embodiments are only used to illustrate the technical solutions of the present disclosure, and not to limit the present application. Although the present disclosure has been described in detail with reference to the foregoing embodiments, it should be understood by those of ordinary skill in the art that: the technical solutions described in the foregoing embodiments may still be modified, or some technical features therein may be equivalently replaced; such modifications or substitutions do not make the corresponding technical solutions depart from the spirit and scope of the embodiments of the present disclosure.

While the preferred embodiments of the specification have been described, additional changes and modifications to those embodiments may occur to those skilled in the art once they learn about the basic inventive concepts. Therefore, it is intended that the appended claims should be interpreted as including the preferred embodiments and all changes and modifications that fall within the scope of the present disclosure.

It will be apparent to those skilled in the art that various modifications and variations may be made to the present disclosure without departing from the spirit and scope of the present disclosure. Therefore, if such modifications and variations to the present disclosure are within the scope of the claims of the present disclosure and their equivalents, the present disclosure is also intended to encompass such modifications and variations.

1. A display panel, comprising: at least two types of subpixel regions, wherein each type of subpixel region is configured to emit one color of light, each subpixel region is provided with a subpixel, and each subpixel is provided with a luminescent material; wherein
each subpixel region of at least one type of subpixel regions is provided with at least two subpixels;
the luminescent material of all the subpixels in any one subpixel region is obtained by means of one opening provided in an evaporation mask plate;
a distance between two adjacent subpixel regions is greater than a distance between two adjacent subpixels in the same subpixel region; and
two adjacent columns of subpixel regions arranged in a first direction comprise different colors of subpixel regions, a distance between two adjacent subpixel regions of the same type in one of the two adjacent columns is a first distance, a size of another type of subpixel region in the other of the two adjacent columns in the first direction is a second distance, and the first distance is less than the second distance.

2. The display panel according to claim 1, further comprising: a pixel defining layer between adjacent subpixels; wherein
each subpixel region of at least one type of subpixel regions is provided with at least two subpixels, and each subpixel region of at least one type of subpixel regions is provided with one subpixel; or,
each subpixel region of all the subpixel regions is provided with at least two subpixels.

3. The display panel according to claim 1, wherein
the subpixel regions comprise a red subpixel region, a green subpixel region, and a blue subpixel region, and the subpixels comprise a red subpixel, a green subpixel, and a blue subpixel;
each blue subpixel region is provided with at least two blue subpixels;
each red subpixel region is provided with one red subpixel; and
each green subpixel region is provided with one green subpixel.

4. The display panel according to claim 3, further comprising: a plurality of pixel units;
each blue subpixel region is provided with four blue subpixels, each pixel unit comprises one red subpixel, one green subpixel, and two blue subpixels.

5. The display panel according to claim 4, wherein
red subpixels and green subpixels are alternately arranged in the first direction;
blue subpixels are arranged consecutively in the first direction; and
a size of the blue subpixel in the first direction is less than a size of the red subpixel in the first direction, and/or the size of the blue subpixel in the first direction is less than a size of the green subpixel in the first direction.

6. The display panel according to claim 1, wherein
the subpixel regions comprise a red subpixel region, a green subpixel region, and a blue subpixel region, and the subpixels comprise a red subpixel, a green subpixel, and a blue subpixel;
each blue subpixel region is provided with at least three blue subpixels;
each red subpixel region is provided with at least two red subpixels; and
each green subpixel region is provided with at least two green subpixels.

7. The display panel according to claim 6, wherein
each blue subpixel region is provided with six blue subpixels, each red subpixel region is provided with four red subpixels, and each green subpixel region is provided with four green subpixels;
or,
some blue subpixel regions are each provided with three blue subpixels, while other blue subpixel regions are each provided with six blue subpixels; some red subpixel regions are each provided with two red subpixels, while other red subpixel regions are each provided with four red subpixels; and some green subpixel regions are each provided with two green subpixels, while other green subpixel regions are each provided with four green subpixels.

8. The display panel according to claim 6, further comprising: a plurality of pixel units, each of which comprises one red subpixel, one green subpixel, and one blue subpixel.

9. The display panel according to claim 7, wherein
blue subpixel regions are arranged consecutively in the first direction;
red subpixel regions and green subpixel regions are alternately arranged in the first direction; and
a size of the blue subpixel in the first direction is greater than a size of the red subpixel in the first direction, and/or the size of the blue subpixel in the first direction is greater than a size of the green subpixel in the first direction.

10. The display panel according to claim 9, wherein
in a second direction, blue subpixel regions and red subpixel regions are alternately arranged, and/or blue subpixel regions and green subpixel regions are alternately arranged; and
the first direction intersects with the second direction.

11. The display panel according to claim 5, wherein
a distance between adjacent blue subpixel regions in the first direction is the first distance; and
a minimum size of the red or green subpixel region in the first direction is the second distance.

12. The display panel according to claim 5, wherein
a distance between adjacent blue subpixel regions in the first direction is the first distance, a shortest distance between the red subpixel region and the green subpixel region adjacent in the first direction is a third distance, and the first distance is greater than the third distance.

13. The display panel according to claim 5, wherein
a size of the blue subpixel region in the first direction is greater than a size of the red subpixel region in the first direction, and/or the size of the blue subpixel region in the first direction is greater than a size of the green subpixel region in the first direction.

14. The display panel according to claim 1, wherein
at least one type of the subpixel regions each have a rectangular shape, and the subpixel regions in the at least one type of the subpixel regions each have a rectangular shape;
an aspect ratio of the shape of the subpixel regions in the at least one type of the subpixel regions is equal to an aspect ratio of a shape of a corresponding subpixel; and/or,
an aspect ratio of the shape of the subpixel regions in the at least one type of the subpixel regions is greater than an aspect ratio of the shape of the corresponding subpixel.

15. The display panel according to claim 1, wherein
a difference between the number of rows and the number of columns of all the subpixels arranged in each subpixel region is 2 or less.

16. The display panel according to claim 9, wherein
the blue subpixel region is provided with three blue subpixels, and the three blue subpixels in the same blue subpixel region are arranged in a single column in the first direction; or
the blue subpixel region is provided with six blue subpixels, and the six blue subpixels in the same blue subpixel region are arranged in two columns in the first direction.

17. The display panel according to claim 1, wherein
two adjacent columns of subpixel regions in the first direction correspond to different colors of emitted light.

18. An evaporation mask plate for preparing the display panel according to claim 1, wherein the evaporation mask plate comprises at least two types of openings, each type configured for correspondingly preparing a luminescent material of one type of subpixel regions in the display panel; wherein
each opening is configured for correspondingly preparing the luminescent material of one subpixel region of the display panel;
a distance between adjacent openings of the two types is greater than a distance between two adjacent subpixels in the same subpixel region of the display panel; and
two adjacent columns of openings in the first direction comprise different types of openings for preparing different colors of luminescent materials, a distance between two adjacent openings of the same type in one of the two adjacent columns is a fourth distance, a size of another type of opening in the other of the two adjacent columns in the first direction is a fifth distance, and the fourth distance is less than the fifth distance.

19. A display apparatus, comprising:
the display panel according to claim 1.

20. The display panel according to claim 9, wherein
a distance between adjacent blue subpixel regions in the first direction is the first distance; and
a minimum size of the red or green subpixel region in the first direction is the second distance.
